(19) United States
(12) Patent Application Publication
(10) Pub. No.: US 2007/0281460 A1
(43) Pub. Date: Dec. 6, 2007

(54) FRONT-END PROCESSED WAFER HAVING THROUGH-CHIP CONNECTIONS

(75) Inventor: John Trezza, Nashua, NH (US)

Correspondence Address: MORGAN & FINNEGAN, L.L.P., 3 WORLD FINANCIAL CENTER, NEW YORK, NY, 10281-2101, US

(73) Assignee: CUBIC WAFER, INC., Merrimack, NH (US)

(21) Appl. No.: 11/617,985

(22) Filed: Dec. 29, 2006

Related U.S. Application Data
(63) Continuation-in-part of application No. 11/422,551, filed on Jun. 6, 2006.
(60) Provisional application No. 60/882,671, filed on Dec. 29, 2006.

(51) Int. Cl. H01L 21/768

(52) U.S. Cl. 438/618; 257/E21.597

(57) ABSTRACT

A method involves forming vias in a blank semiconductor wafer, making at least some of the vias in the blank semiconductor wafer electrically conductive, and performing front end processing on the blank wafer so as to create devices on the wafer that are connected to the electrically conductive vias.

### CROSS REFERENCE TO RELATED APPLICATIONS

This application is a continuation-in-part of U.S. patent application Ser. No. 11/422,551, and further claims the benefit of priority, pursuant to 35 U.S.C. 119(e), of U.S. Provisional Application Ser. No. 60/882,671 filed Dec. 29, 2006. The entirety of both are incorporated herein by reference as if fully set forth herein.

### FIELD OF THE INVENTION

The present invention relates to semiconductors and, more particularly, to electrical connections for such devices.

### BACKGROUND

It is sometimes desirable to be able to form electrical connections through a chip to facilitate connecting it to another element in an efficient manner. In many cases, this means use of vias and involve connections that are made near the devices of chips as opposed to forming connections at or near the periphery of the chip, as is done with conventional methods.

One drawback to using through-chip vias on fully processed (i.e. device-bearing) chips is that fully formed chips are significantly more expensive than the cost of a comparable piece of blank wafer and, if an error is made in aligning where the via for the electrical connection will be, a device on the chip may be damaged or the desired connection may not be made. In either case, this could result in the chip being useless and necessitate scrapping the chip.

### SUMMARY OF THE INVENTION

We have devised a way to minimize the risk and cost associated with the use of through-chip electrical connections in conjunction with device-bearing chips. By forming the through-chip connections on a blank wafer, the risk of damaging devices is advantageously eliminated (because there are no devices to damage). Moreover, in the event of a problem that renders the wafer unusable, the cost effect is also reduced because the wafer has not yet undergone any device creation or back-end processing procedures.

One aspect of the approach involves a method. The method involves forming vias in a blank semiconductor wafer, making at least some of the vias in the blank semiconductor wafer electrically conductive, and performing front end processing on the blank wafer so as to create devices on the wafer that are connected to the electrically conductive vias.

The advantages and features described herein are a few of the many advantages and features available from representative embodiments and are presented only to assist in understanding the invention. It should be understood that they are not to be considered limitations on the invention as defined by the claims, or limitations on equivalents to the claims. For instance, some of these advantages are mutually contradictory, in that they cannot be simultaneously present in a single embodiment. Similarly, some advantages are applicable to one aspect of the invention, and inapplicable to others. Thus, this summary of features and advantages should not be considered dispositive in determining equivalence. Additional features and advantages of the invention will become apparent in the following description, from the drawings, and from the claims.

### BRIEF DESCRIPTION OF THE DRAWINGS

FIG. 1 illustrates, in simplified form, a portion of a blank wafer which will be used to illustrate the process;

FIG. 2 illustrates, in simplified form, the portion of the wafer of FIG. 1 after formation of the vias;

FIG. 3 illustrates, in simplified form, the vias of FIG. 2 after the simple via and one of the annular vias has been filled with metal; and

FIG. 4 illustrates, in simplified form, the portion of the wafer of FIG. 1 after front end processing is complete.

### DETAILED DESCRIPTION

U.S. patent applications, Ser. Nos. 11/329,481, 11/329,506, 11/329,539, 11/329,540, 11/329,556, 11/329,557, 11/329,558, 11/329,574, 11/329,575, 11/329,576, 11/329,873, 11/329,874, 11/329,875, 11/329,883, 11/329,885, 11/329,886, 11/329,887, 11/329,952, 11/329,953, 11/329,955, 11/330,011 and 11/422,551, incorporated herein by reference describe various techniques for forming small, deep vias in, and electrical contacts for, semiconductor wafers. Our techniques allow for via densities and placement that was previously unachievable and can be performed on a chip or wafer scale.

In cases where it is desirable to create through-chip electrical connections, but minimize the risks involved with fully processed wafers (i.e. device bearing wafers), the following approach can be used.

In summary overview, the approach straightforwardly involves forming vias in a blank wafer at the locations where they should be relative to devices that would be on the wafer once front end processing is complete, making the vias electrically conductive and then fabricating the devices on the wafer, thereby making the connections between the devices and the through-chip connections by virtue of the device fabrication process.

Specifically, the process starts with a blank wafer, for example, a silicon (Si), germanium (Ge), silicon-germanium (SiGe), gallium-arsenide (GaAs), indium phosphide (InP) or other wafer.

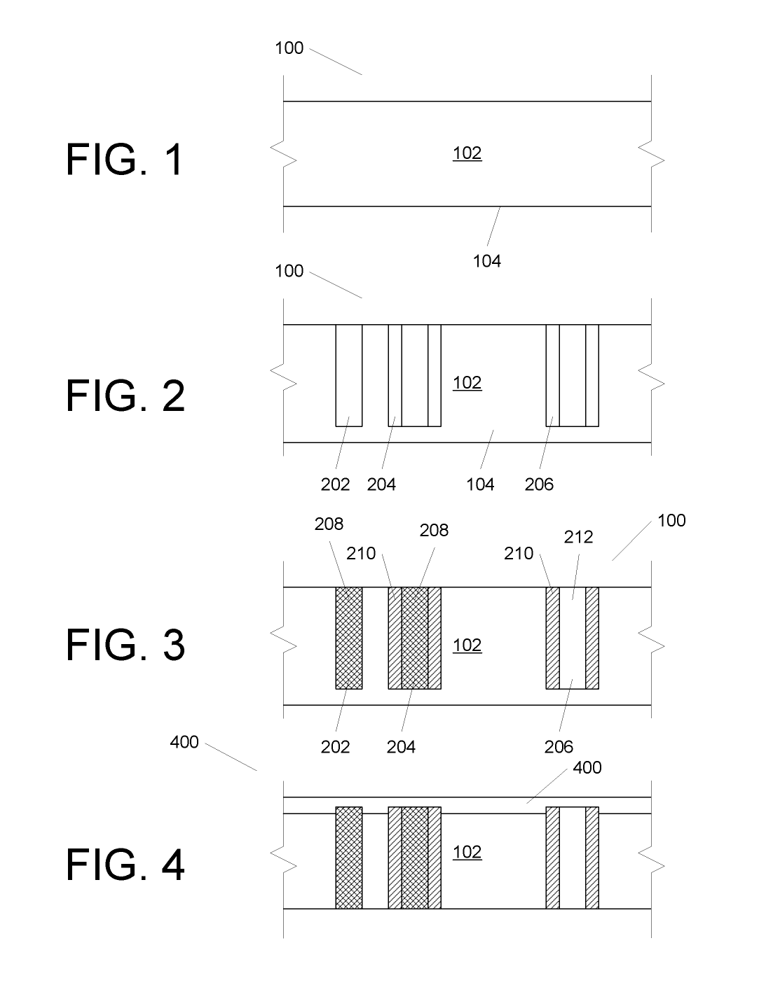

FIG. 1 illustrates, in simplified form, a cross section of a portion 100 of a blank wafer 102 which will be used to illustrate the process. Note that scales are grossly distorted for simplicity of presentation.

Next, vias are formed in the wafer at pre-selected locations on the wafer that correspond to where they would be made if the devices had already been formed. Depending upon the particular implementation this can involve formation of the vias using, for example, one of the techniques described in the above-incorporated applications. Alternatively, or additionally, vias can be formed by other processes including, for example, laser drilling.

FIG. 2 illustrates, in simplified form, the portion 100 of the blank wafer 102 after formation of the vias 202, 204, 206. As shown, the vias in the portion include one simple via 202 and two annular vias 204, 206. Note that, because annular vias are used, the vias do not extend completely through the wafer, but rather stop a short distance from the bottom surface 104 of the wafer to prevent the control post from falling out.

Once the vias have been formed, they are made electrically conductive by filling them with a conductor that can withstand the temperatures and stresses involved in the particular front end processing steps and specifically, device creation. For example, if CMOS processing will be performed, the conductor could be any of Au, Cu, Ni, W, Ti or any other metal or alloy that can withstand the temperatures of 1000° C. or so involved in the CMOS processing.

Depending upon the particular implementation, this can involve filling the vias using a vapor deposition process, a plating process or any other process which will result in filling of the vias. Alternatively, if an annular via process is used, the annular vias can be filled with a suitably robust insulator and the central posts can be left intact (i.e. not removed) so that, during front end processing, the central posts can be suitably doped and thereby act as the conductor itself and eliminating the need for any metal at all in such vias.

FIG. 3 illustrates, in simplified form, the vias 202, 204, 206 of FIG. 2 after the simple via 202 has been filled with metal 208 and one of the annular vias 202 (which has had its central post removed) and the space left by the removal has also been filled with metal 208. Note that both of the annular vias 204, 206 have been filled with a suitable insulator 210. However, the central post 212 within the second annular via 206 has not been removed so that it can become a conductor during front end processing.

In the case where annular vias have been used, the bottom surface 104 of the wafer can now be thinned to expose the conductor metal 208 or the bottom of a central post 212. As will be recognized, this thinning will not have an effect on the via 206 where the central post 212 was retained because the insulator 210 holds it in place. Of course, if annular vias are not used, the via can extend through the wafer or not as desired, bearing in mind that the latter case will likely require thinning unless, for example, capacitive connections are contemplated.

In another alternative variant, the vias will not extend fully through the wafer, and the region between the bottom of the wafer and the via is maintained at sufficient dimensions so that it can become the device region during front end processing.

At this point, the processing of the instant approach is finished and the wafer now contains a full set of conductive, vias.

Thereafter, the wafer can undergo the normal front end and back-end processing and dicing in the conventional manner. Once that processing is complete, the final chip will have the same kind of through-chip connections as it could have had by performing one of the above-incorporated approaches on a fully processed chip but at a much lower risk and, potentially, with a higher yield.

FIG. 4 illustrates, in simplified form, the portion of the wafer of FIG. 1 after front end processing is complete. Thus, as shown in FIG. 4, the wafer has become a front-end processed wafer 400 and now includes a doped region 402 where devices can be present. Advantageously, the vias, by virtue of their location relative to the devices, are now electrically connected to the appropriate parts of the devices.

It should thus be understood that this description (including the figures) is only representative of some illustrative embodiments. For the convenience of the reader, the above description has focused on a representative sample of all possible embodiments, a sample that teaches the principles of the invention. The description has not attempted to exhaustively enumerate all possible variations. That alternate embodiments may not have been presented for a specific portion of the invention, or that further undescribed alternate embodiments may be available for a portion, is not to be considered a disclaimer of those alternate embodiments. One of ordinary skill will appreciate that many of those undescribed embodiments incorporate the same principles of the invention and others are equivalent.

What is claimed is:

1. A method comprising:
forming vias in a blank semiconductor wafer;
making at least some of the vias in the blank semiconductor wafer electrically conductive; and
performing front end processing on the blank wafer so as to create devices on the wafer that are connected to the electrically conductive vias.

2. The method of claim 1, wherein the forming vias comprises:
forming annular vias.

3. The method of claim 2, wherein the forming the annular vias comprises:
removing at least one central post.

4. The method of claim 2, wherein the forming the annular vias comprises:
keeping at least one central post intact so that it can be made electrically conductive during the front end processing of the blank semiconductor wafer.

5. The method of claim 1, wherein the making at least some of the vias in the blank semiconductor wafer electrically conductive comprises:
filling the via with one of a metal or metal alloy.

6. The method of claim 1, wherein the forming vias comprises:
forming the vias to a depth that is less than a depth that would go through the wafer.

7. The method of claim 6 wherein the performing front end processing comprises:
forming a device in a region located near a bottom of at least one via.

8. The method of claim 1, wherein the performing front end processing comprises:
forming a device in a region located near an outer end of at least one via.

9. The method of claim 1, further comprising:
thinning a side of the wafer closest to a bottom of at least one via.
